(19) United States
(12) Patent Application Publication
(10) Pub. No.: US 2014/0070222 A1
(43) Pub. Date: Mar. 13, 2014

(54) THIN-FILM TRANSISTOR AND SOLID-STATE IMAGING APPARATUS

(71) Applicant: Tatsuya OHGURO, Kanagawa (JP)

(72) Inventor: Tatsuya OHGURO, Kanagawa (JP)

(21) Appl. No.: 13/724,801

(22) Filed: Dec. 21, 2012

(30) Foreign Application Priority Data
Sep. 13, 2012 (JP) 2012-201474

(51) Int. Cl. H01L 29/786; H01L 31/12

(52) U.S. Cl. CPC H01L 29/786; H01L 31/12
USPC 257/66; 257/59; 257/72

(57) ABSTRACT

According to one embodiment, a thin-film transistor includes a thin-film semiconductor layer, a first gate electrode provided on the thin-film semiconductor layer through a first gate insulation film without overlapping an edge portion of the thin-film semiconductor layer, a source layer connected to the thin-film semiconductor layer, and a drain layer connected to the thin-film semiconductor layer.

### CROSS-REFERENCE TO RELATED APPLICATIONS

This application is based upon and claims the benefit of priority from Japanese Patent Application No. 2012-201474, filed on Sep. 13, 2012; the entire contents of which are incorporated herein by reference.

### FIELD

Embodiments of the present invention relate to thin-film transistors and solid-state imaging apparatuses.

### BACKGROUND

A thin-film transistor can be formed on an insulator, and is effective for lamination of semiconductor devices. Factors of 1/f noise of the thin-film transistor include the capture and emission of carriers in a trap site at an interface between a gate insulation film and a channel, and the capture and emission of carriers in a trap site at an end portion in a gate width direction.

### BRIEF DESCRIPTION OF THE DRAWINGS

FIG. 1A is a cross-sectional view illustrating a schematic configuration of a thin-film transistor according to a first embodiment, and

FIG. 1B is a plan view illustrating a schematic configuration of the thin-film transistor according to the first embodiment;

FIGS. 2A to 2F are cross-sectional views illustrating a method for manufacturing a thin-film transistor according to a second embodiment;

FIG. 3 is a cross-sectional view illustrating a schematic configuration of a thin-film transistor according to a third embodiment;

FIG. 4 is a plan view illustrating a schematic configuration of a thin-film transistor according to a fourth embodiment;

FIG. 5 is a cross-sectional view illustrating a schematic configuration of a thin-film transistor according to a fifth embodiment;

FIG. 6 is a cross-sectional view illustrating a schematic configuration of a thin-film transistor according to a sixth embodiment;

FIG. 7 is a plan view illustrating a schematic configuration of a thin-film transistor according to a seventh embodiment;

FIG. 8 is a plan view illustrating a schematic configuration of a thin-film transistor according to an eighth embodiment;

FIG. 9 is a plan view illustrating a schematic configuration of a thin-film transistor according to a ninth embodiment;

FIG. 10 is a plan view illustrating a schematic configuration of a thin-film transistor according to a tenth embodiment;

FIG. 11 is a plan view illustrating a schematic configuration of a thin-film transistor according to an eleventh embodiment;

FIG. 12 is a cross-sectional view illustrating a schematic configuration of a pixel of a solid-state imaging apparatus according to a twelfth embodiment;

FIG. 13 is a diagram illustrating a circuit configuration of the pixel of FIG. 12;

FIGS. 14A and 14B are cross-sectional views illustrating a method for manufacturing a pixel of a solid-state imaging apparatus according to a thirteenth embodiment;

FIGS. 15A and 15B are cross-sectional views illustrating the method for manufacturing the pixel of the solid-state imaging apparatus according to the thirteenth embodiment;

FIGS. 16A and 16B are cross-sectional views illustrating the method for manufacturing the pixel of the solid-state imaging apparatus according to the thirteenth embodiment;

FIGS. 17A and 17B are cross-sectional views illustrating the method for manufacturing the pixel of the solid-state imaging apparatus according to the thirteenth embodiment;

FIGS. 18A and 18B are cross-sectional views illustrating the method for manufacturing the pixel of the solid-state imaging apparatus according to the thirteenth embodiment;

FIGS. 19A and 19B are cross-sectional views illustrating the method for manufacturing the pixel of the solid-state imaging apparatus according to the thirteenth embodiment;

FIGS. 20A and 20B are cross-sectional views illustrating the method for manufacturing the pixel of the solid-state imaging apparatus according to the thirteenth embodiment; and

FIGS. 21A and 21B are cross-sectional views illustrating the method for manufacturing the pixel of the solid-state imaging apparatus according to the thirteenth embodiment.

### DETAILED DESCRIPTION

In general, according to one embodiment, a thin-film transistor includes a thin-film semiconductor layer, a first gate electrode provided on the thin-film semiconductor layer through a first gate insulation film without overlapping an edge portion of the thin-film semiconductor layer, a source layer connected to the thin-film semiconductor layer, and a drain layer connected to the thin-film semiconductor layer.

Hereinafter, thin-film transistors and solid-state imaging apparatuses according to embodiments will be described in detail with reference to the accompanying drawings. Also, the present invention is not limited by these embodiments.

### First Embodiment

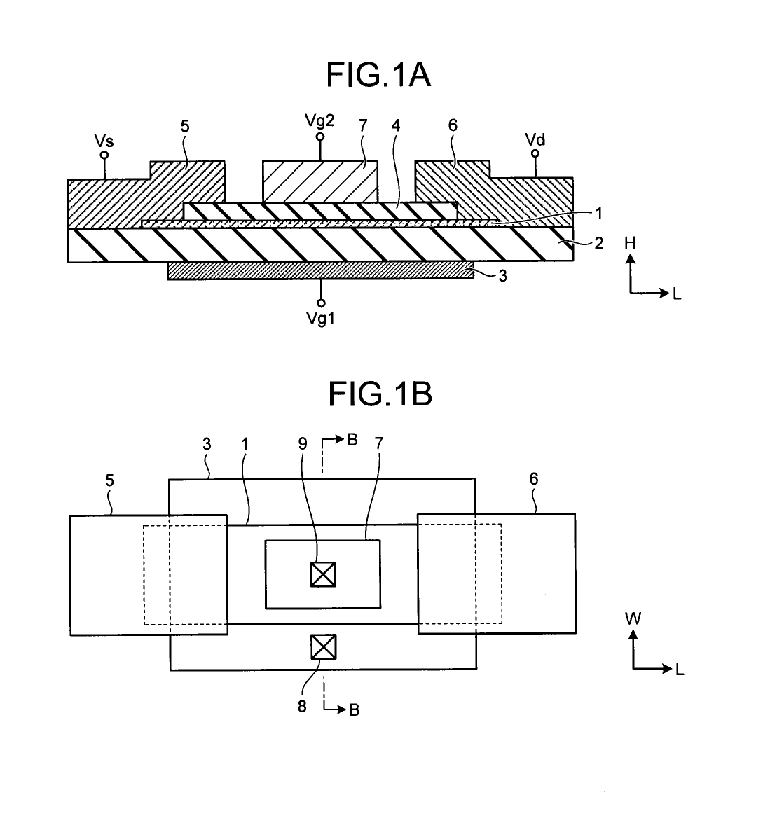

FIG. 1A is a cross-sectional view illustrating a schematic configuration of a thin-film transistor according to a first embodiment, and FIG. 1B is a plan view illustrating a schematic configuration of the thin-film transistor according to the first embodiment.

Referring to FIGS. 1A and 1B, a gate electrode 3 is provided under a thin-film semiconductor layer 1 through a gate insulation film 2. Also, a gate electrode 7 is provided on the thin-film semiconductor layer 1 through a gate insulation film 4. Also, the gate electrode 7 may be disposed without overlapping an edge portion of the thin-film semiconductor layer 1. Also, the gate insulation film 4 may be set to have a smaller effective film thickness than the gate insulation film 2. Then, on the thin-film semiconductor layer 1, a source layer 5 is connected to one end of the thin-film semiconductor layer 1 in a gate length direction L, and a drain layer 6 is connected to the other end.

Here, a gate contact 9 is formed on the gate electrode 7. Also, the gate electrode 3 is exposed from the thin-film semiconductor layer 1 and extends in the gate length direction L. Then, a gate contact 8 is formed on the gate electrode 3 without overlapping the thin-film semiconductor layer 1.

Also, a material of the thin-film semiconductor layer 1 may be, for example, a polycrystal silicon or an oxide semiconductor such as IGZO (indium gallium zinc oxide). A material of the gate insulation film 2 may be, for example, a silicon nitride film. A material of the gate insulation film 4 may be, for example, a silicon oxide film. A material of the gate electrode 3 may be, for example, a metal such as Cu. Materials of the source layer 5, the drain layer 6, and the gate electrode 7 may be, for example, metals such as Al, Cu, and Mo. Alternatively, materials of the source layer 5, the drain layer 6, and the gate electrode 7 may be a three-layer structure of TiN—Al—TiN.

Then, a source voltage Vs is applied to the source layer 5, a drain voltage Vd is applied to the drain layer 6, a gate voltage Vg1 is applied to the gate electrode 3, and a gate voltage Vg2 is applied to the gate electrode 7. At this time, the source voltage Vs may be set to a ground potential, and the drain voltage Vd and the gate voltages Vg1 and Vg2 may be set to positive potentials. Also, values of the gate voltages Vg1 and Vg2 may be equal to or different from each other as long as the gate voltages Vg1 and Vg2 are positive potentials.

Here, since the gate electrodes 3 and 7 are provided on both surfaces of the thin-film semiconductor layer 1, an electric field in a direction from a channel to the gate insulation films 2 and 4 can be alleviated. Also, since the gate electrode 7 is disposed without overlapping the edge portion of the thin-film semiconductor layer 1, an increase in the electric field at the edge portion of the thin-film semiconductor layer 1 can be suppressed. Therefore, the capture and emission of carriers in a trap site at interfaces between the gate insulation films 2 and 4 and the channel can be reduced while suppressing an increase in the capture and emission of carriers at the edge portion of the thin-film semiconductor layer 1. Accordingly, 1/f noise of the thin-film transistor can be reduced. Also, since the gate insulation film 4 is set to have a smaller effective film thickness than the gate insulation film 2, the effect of alleviating a vertical electric field can be increased.

### Second Embodiment

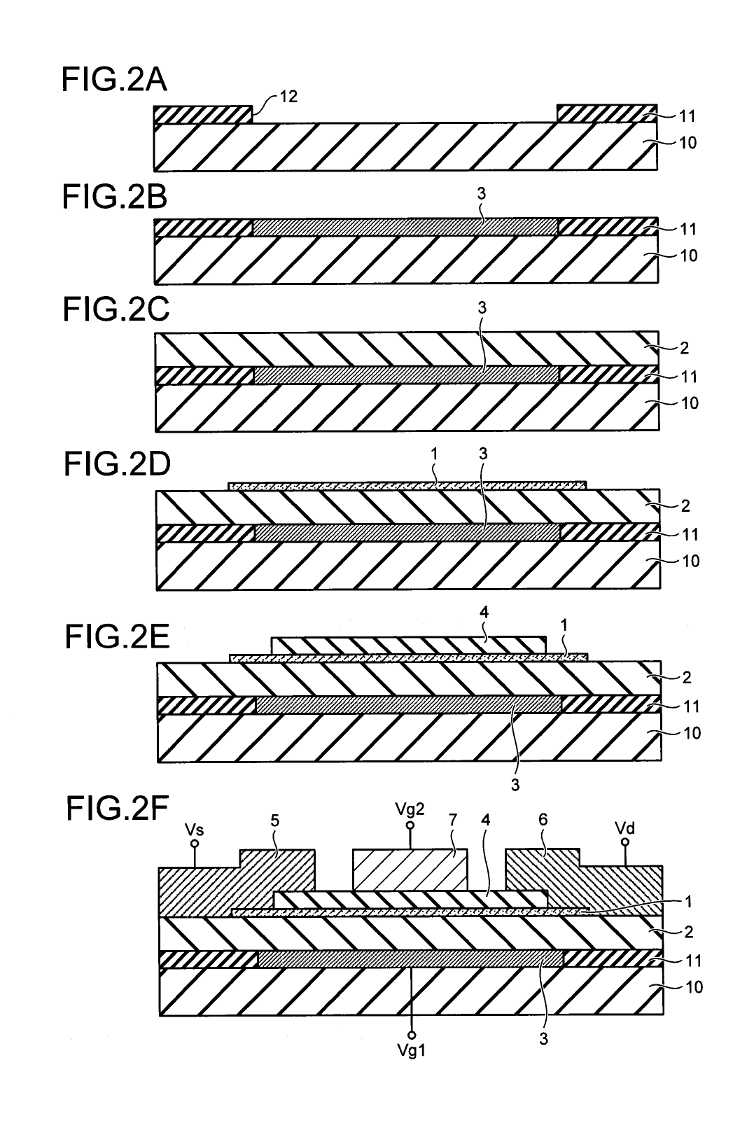

FIGS. 2A to 2F are cross-sectional views illustrating a method for manufacturing a thin-film transistor according to a second embodiment.

Referring to FIG. 2A, an insulation layer 11 is formed on an underlayer 10 by a method such as CVD. Also, the underlayer 10 may be an insulation layer or an interconnection layer. Also, an integrated circuit may be formed in the underlayer 10. Then, an opening portion 12 is formed in the insulation layer 11 by using a photolithography technique and a dry etching technique.

Subsequently, as illustrated in FIG. 2B, an electrode material is formed on the insulation layer 11 by a method such as sputtering or CVD, such that the opening portion 12 is buried. Then, a gate electrode 3 buried in the opening portion 12 is formed on the underlayer 10 by thinning the electrode material by a method such as CMP until the insulation layer 11 is exposed.

Subsequently, as illustrated in FIG. 2C, a gate insulation film 2 is formed on the gate electrode 3 and the insulation layer 11 by a method such as CVD.

Subsequently, as illustrated in FIG. 2D, a thin-film semiconductor layer 1 is formed on the gate insulation film 2 by a method such as sputtering or CVD. Then, by using a photolithography technique and an etching technique, the thin-film semiconductor layer 1 is patterned to face the gate electrode 3. When IGZO is used as a material of the thin-film semiconductor layer 1, dry etching by chlorine-based gas may be used, or wet etching by acid chemicals may be used.

Subsequently, as illustrated in FIG. 2E, a gate insulation film 4 is formed on the thin-film semiconductor layer 1 by a method such as CVD. Then, both end portions of the thin-film semiconductor layer 1 are exposed by patterning the gate insulation film 4 by using a photolithography technique and a dry etching technique.

Subsequently, as illustrated in FIG. 2F, an electrode material is formed on the gate insulation films 2 and 4 and the thin-film semiconductor layer 1 by a method such as sputtering or CVD. Then, by patterning the electrode material by using a photolithography technique and an etching technique, a source layer 5 and a drain layer 6 connected to end portions of the thin-film semiconductor layer 1 are formed, and a gate electrode 7 disposed to face the gate electrode 3 is formed on the gate insulation film 4 without overlapping the end portions of the thin-film semiconductor layer 1.

### Third Embodiment

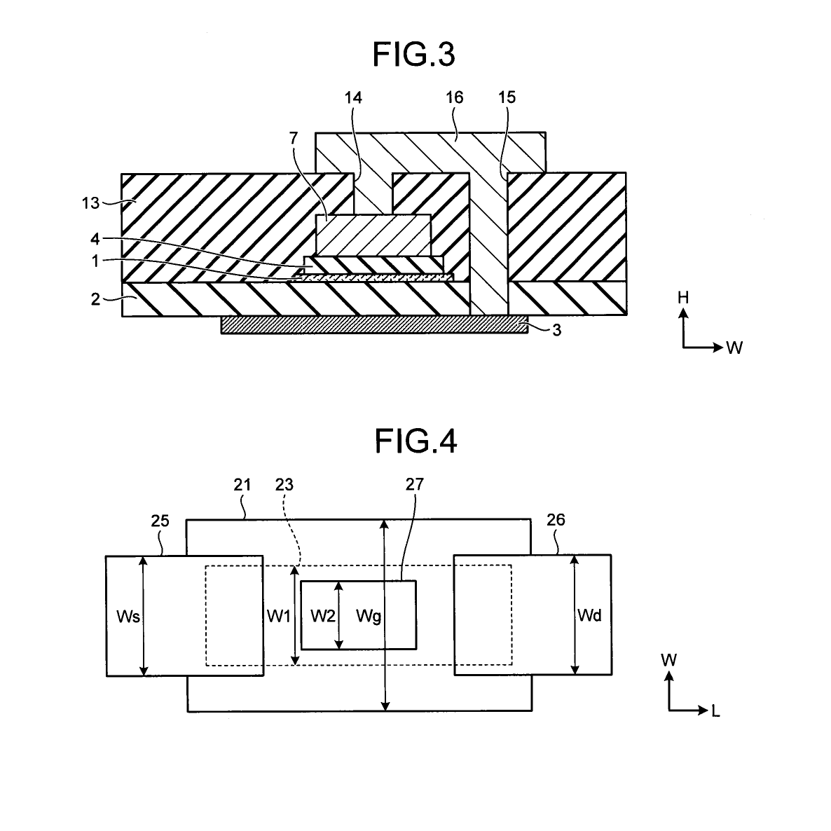

FIG. 3 is a cross-sectional view illustrating a schematic configuration of a thin-film transistor according to a third embodiment.

Referring to FIG. 3, an interlayer insulation layer 13 is formed on the gate insulation film 2 and the gate electrode 7 of FIG. 1. Also, a material of the interlayer insulation layer 13 may be, for example, a silicon oxide film. Then, an opening portion 14 exposing the gate electrode 7 is formed in the interlayer insulation layer 13, and an opening portion 15 exposing the gate electrode 3 is formed in the interlayer insulation layer 13 and the gate insulation film 2. Then, an interconnection 16 buried in the opening portions 14 and 15 is formed on the interlayer insulation layer 13, and the gate electrodes 3 and 7 are connected to each other through the interconnection 16.

Here, since the gate electrodes 3 and 7 are connected to each other, a positive voltage can be applied from both surfaces of the thin-film semiconductor layer 1. Therefore, the capture and emission of carriers in a trap site at interfaces between the gate insulation films 2 and 4 and the channel can be reduced, and thus, 1/f noise of the thin-film transistor can be reduced.

### Fourth Embodiment

FIG. 4 is a plan view illustrating a schematic configuration of a thin-film transistor according to a fourth embodiment.

Referring to FIG. 4, in the thin-film transistor, a gate electrode 23 is provided under a thin-film semiconductor layer 21. Also, a gate electrode 27 is provided on the thin-film semiconductor layer 21 to face the gate electrode 23. Also, the gate electrodes 23 and 27 may be disposed without overlapping edge portions of the thin-film semiconductor layer 21. Then, on the thin-film semiconductor layer 21, a source layer 25 is connected to one end of the thin-film semiconductor layer 21 in a gate length direction L, and a drain layer 26 is connected to the other end. Also, the source layer 25 and the drain layer 26 may be disposed without overlapping edge portions of the thin-film semiconductor layer 21 in a gate width direction W. At this time, when a width of the thin-film semiconductor layer 21 is Wg; a width of the source layer 25 is Ws; a width of the drain layer 26 is Wd; a gate width of the gate electrode 23 is W1; and a gate width of the gate electrode 27 is W2, the conditions of Wg>W1>W2; Wg>Ws; and Wg>Wd can be satisfied.

Here, since the gate electrodes 23 and 27 are disposed without overlapping the edge portions of the thin-film semiconductor layer 21, an electric field applied to the edge portions of the thin-film semiconductor layer 21 can be alleviated. Therefore, the capture and emission of carriers at the edge portions of the thin-film semiconductor layer 21 can be reduced, and thus, 1/f noise of the thin-film transistor can be reduced. In addition, since the source layer 25 and the drain layer 26 are disposed without overlapping the edge portions of the thin-film semiconductor layer 21 in the gate width direction W, the capture and emission of carriers at the edge portions of the thin-film semiconductor layer 21 can be reduced, and thus, 1/f noise of the thin-film transistor can be reduced.

### Fifth Embodiment

FIG. 5 is a cross-sectional view illustrating a schematic configuration of a thin-film transistor according to a fifth embodiment.

Referring to FIG. 5, a gate insulation film 22 is formed between the thin-film semiconductor layer 21 and the gate electrode 23 of FIG. 4, and a gate insulation film 24 is formed between the thin-film semiconductor layer 21 and the gate electrode 27. Also, an interlayer insulation layer 29 is formed on the gate insulation film 22 and the gate electrode 27, and an interlayer insulation layer 28 is formed under the gate insulation film 22 and the gate electrode 23. Also, a material of the interlayer insulation layers 28 and 29 may be, for example, a silicon oxide film. Then, an opening portion 32 exposing the gate electrode 27 is formed in the interlayer insulation layer 29, an opening portion 33 exposing the gate electrode 23 is formed in the interlayer insulation layer 28, and an opening portion 34 penetrating the interlayer insulation layers 28 and 29 and the gate insulation film 22 is formed in the interlayer insulation layers 28 and 29 and the gate insulation film 22. Then, an interconnection 30 buried in the opening portion 33 is formed under the interlayer insulation layer 28, an interconnection 31 buried in the opening portions 32 and 34 is formed on the interlayer insulation layer 29, and the gate electrodes 23 and 27 are connected to each other through the interconnections 30 and 31.

Here, since the gate electrodes 23 and 27 are connected to each other through the interconnections 30 and 31, a positive voltage can be applied from both surfaces of the thin-film semiconductor layer 21 while the gate electrodes 23 and 27 are disposed without overlapping the edge portions of the thin-film semiconductor layer 21. Therefore, the capture and emission of carriers in a trap site at interfaces between the gate insulation films 22 and 24 and the channel can be reduced while reducing the capture and emission of carriers at the edge portions of the thin-film semiconductor layer 21. Accordingly, 1/f noise of the thin-film transistor can be reduced.

### Sixth Embodiment

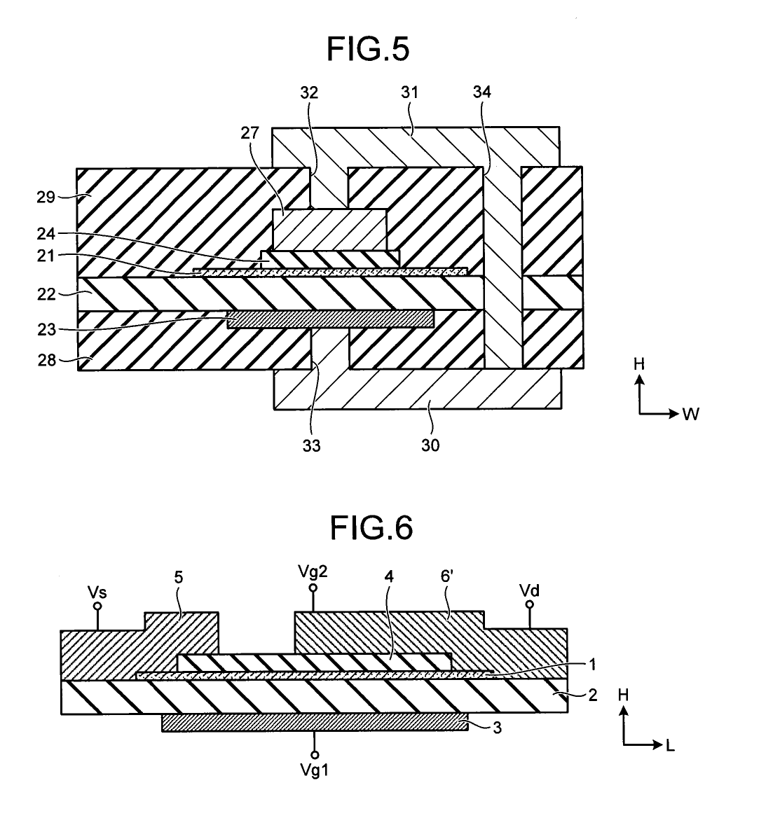

FIG. 6 is a cross-sectional view illustrating a schematic configuration of a thin-film transistor according to a sixth embodiment.

Referring to FIG. 6, in the thin-film transistor, the gate electrode 7 of the thin-film transistor of FIG. 1 is removed, and a drain layer 6′ is provided instead of the drain layer 6. Here, the drain layer 6′ may be more overhung on the gate electrode 3 in the gate length direction L than the source layer 5. That is, the drain layer 6′ may be set to have a larger overlapping area with respect to the gate electrode 3 than the source layer 5.

Herein, since the drain layer 6′ is set to have a larger overlapping area with respect to the gate electrode 3 than the source layer 5, a positive voltage can be applied to both surfaces of the thin-film semiconductor layer 1 in the drain layer 6′ side. Therefore, since a vertical electric field can be more alleviated in the drain layer 6′ side than in the source layer 5, 1/f noise caused by the capture and emission of carriers in the trap site can be reduced as compared to the case of increasing the overlapping area of the source layer 5 with respect to the gate electrode 3.

### Seventh Embodiment

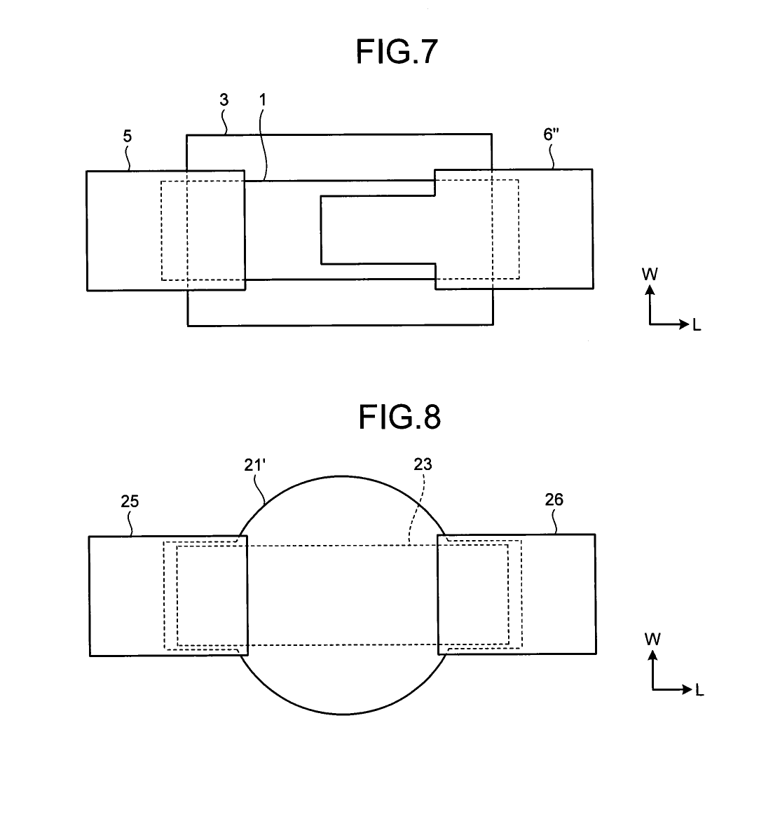

FIG. 7 is a plan view illustrating a schematic configuration of a thin-film transistor according to a seventh embodiment.

Referring to FIG. 7, in the thin-film transistor, a drain layer 6″ is provided instead of the drain layer 6′ of the thin-film transistor of FIG. 6. Here, the drain layer 6″ may be more E on the gate electrode 3 in the gate length direction L than the source layer 5. That is, the drain layer 6′ may have a larger overlapping area with respect to the gate electrode 3 than the source layer 5. Also, an overhang portion of the drain layer 6″ may not be across the thin-film semiconductor layer 1 in the gate width direction W, and a width of the drain layer 6″ may be smaller than a width of the source layer 5.

Here, since the drain layer 6″ has a larger overlapping area with respect to the gate electrode 3 than the source layer 5, and the overhang portion of the drain layer 6″ is not across the thin-film semiconductor layer 1 in the gate width direction W. Therefore, the capture and emission of carriers in the trap site of the channel interface can be reduced while reducing the capture and emission of carriers at the edge portions of the thin-film semiconductor layer 1 in the drain layer 6″ side. Accordingly, the 1/f noise can be reduced.

### Eighth Embodiment

FIG. 8 is a plan view illustrating a schematic configuration of a thin-film transistor according to an eighth embodiment.

Referring to FIG. 8, in the thin-film transistor, the gate electrode 27 of the thin-film transistor of FIG. 4 is removed, and a thin-film semiconductor layer 21′ is provided instead of the thin-film semiconductor layer 21. An edge portion of the thin-film semiconductor layer 21′ is curved to the outside between the drain layer 26 and the source layer 25.

Here, since the edge portion of the thin-film semiconductor layer 21′ is curved to the outside, the length of the edge portion can be increased as compared to the case when the edge portion of the thin-film semiconductor layer 21′ is extended straight. Therefore, the number of carriers passing through the edge portion of the thin-film semiconductor layer 21′ can be reduced, and thus, 1/f noise caused by the capture and emission of carriers in a trap site of the edge portion can be reduced.

### Ninth Embodiment

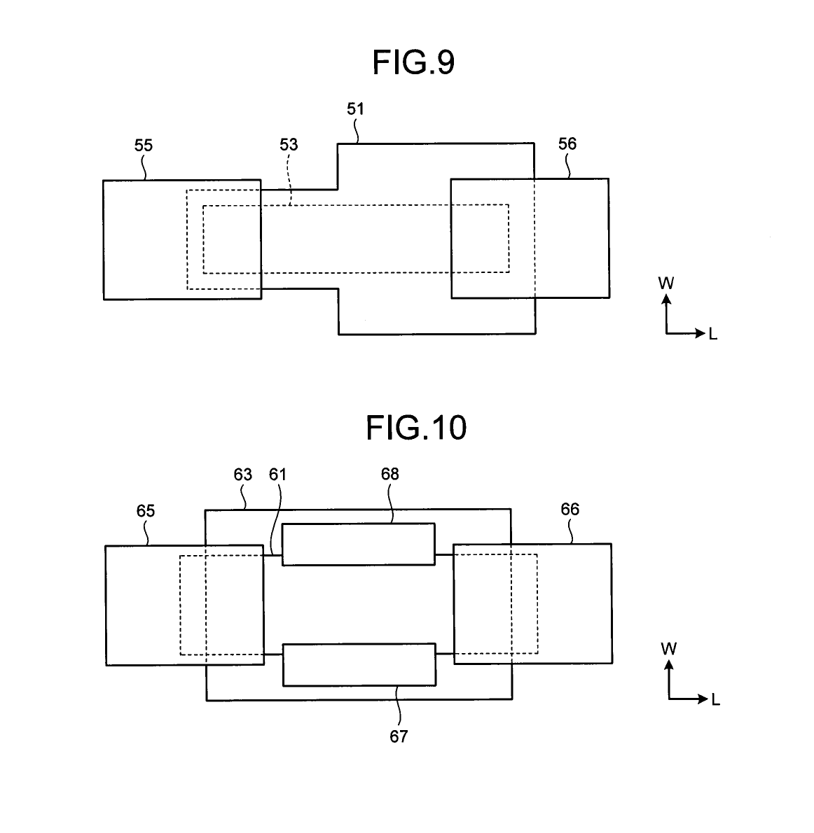

FIG. 9 is a plan view illustrating a schematic configuration of a thin-film transistor according to a ninth embodiment.

Referring to FIG. 9, a gate electrode 53 is provided under a thin-film semiconductor layer 51. Then, on the thin-film semiconductor layer 51, a source layer 55 is connected to one end of the thin-film semiconductor layer 51 in a gate length direction L, and a drain layer 56 is connected to the other end. Here, the thin-film semiconductor layer 51 is more widened at the drain layer 56 side than at the source layer 55 side. At this time, the gate electrode 53 and the drain layer 56 may be disposed without overlapping edge portions of the thin-film semiconductor layer 51 in a gate width direction W.

Here, since the gate electrode 53 and the drain layer 56 are disposed without overlapping the edge portions of the thin-film semiconductor layer 51 in the drain layer 56, an electric field applied to the edge portions of the thin-film semiconductor layer 51 can be alleviated. Therefore, the capture and emission of carriers at the edge portions of the thin-film semiconductor layer 51 in the drain layer 56 side can be reduced, and thus, 1/f noise of the thin-film transistor can be reduced.

### Tenth Embodiment

FIG. 10 is a plan view illustrating a schematic configuration of a thin-film transistor according to a tenth embodiment.

Referring to FIG. 10, in the thin-film transistor, a gate electrode 63 is provided under a thin-film semiconductor layer 61. Then, on the thin-film semiconductor layer 61, a source layer 65 is connected to one end of the thin-film semiconductor layer 61 in a gate length direction L, and a drain layer 66 is connected to the other end. Also, between the source layer 65 and the drain layer 66, edge control layers 67 and 68 are provided at edge portions of the thin-film semiconductor layer 61. Also, the edge control layers 67 and 68 may be a negatively-charged film that is negatively charged. For example, TiO, HfO, or the like may be used as the negatively-charged film.

Also, in the embodiment of FIG. 10, a method for protruding the gate electrode 63, the source layer 65, and the drain layer 66 from the thin-film semiconductor layer 61 in the gate width direction W is illustrated. However, the gate electrode 63, the source layer 65, and the drain layer 66 may be disposed without overlapping the edge portions of the thin-film semiconductor layer 61 in the gate length direction L.

Herein, since the edge control layers 67 and 68 are disposed at the edge portions of the thin-film semiconductor layer 61, the number of carriers passing through the edge portions of the thin-film semiconductor layer 61 can be reduced. Therefore, the capture and emission of carriers at the edge portions of the thin-film semiconductor layer 61 can be reduced, and thus, 1/f noise of the thin-film transistor can be reduced.

### Eleventh Embodiment

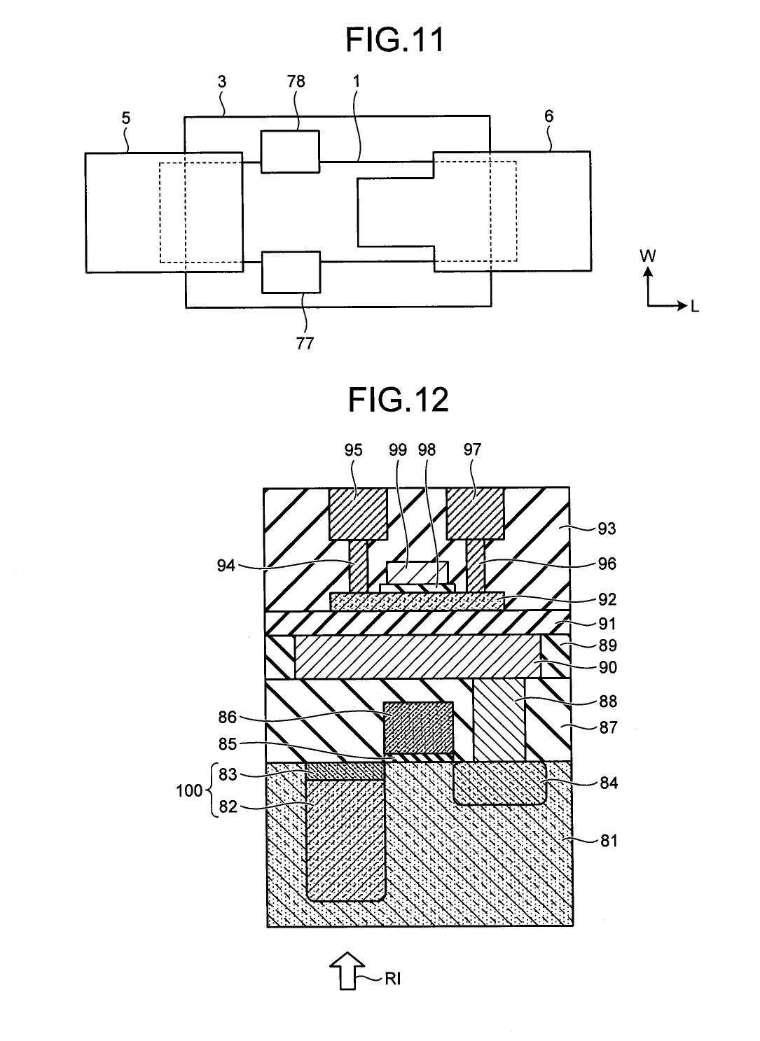

FIG. 11 is a plan view illustrating a schematic configuration of a thin-film transistor according to an eleventh embodiment.

Referring to FIG. 11, in the thin-film transistor, edge control layers 77 and 78 are added to the thin-film transistor of FIG. 7. The edge control layers 77 and 78 are disposed at edge portions of a thin-film semiconductor layer 1 between a source layer 5 and a drain layer 6. Also, the edge control layers 77 and 78 may be a negatively-charged film that is negatively charged. For example, TiO, HfO, or the like may be used as the negatively-charged film. Alternatively, the edge control layers 77 and 78 may be an electrode to which a negative voltage is applied.

Herein, since the edge control layers 77 and 78 are disposed at the edge portions of the thin-film semiconductor layer 1, the number of carriers passing through the edge portions of the thin-film semiconductor layer 1 can be reduced. Therefore, the capture and emission of carriers at the edge portions of the thin-film semiconductor layer 1 can be reduced, and thus, 1/f noise of the thin-film transistor can be reduced.

### Twelfth Embodiment

FIG. 12 is a cross-sectional view illustrating a schematic configuration of a solid-state imaging device according to a twelfth embodiment.

Referring to FIG. 12, in a P-type semiconductor layer 81, an N-type impurity introduction layer 82 and a P-type impurity introduction layer 83 are formed, so that a photoelectric conversion layer 100 is formed. Also, a semiconductor material of the P-type semiconductor layer 81 may be selected from, for example, Si, Ge, SiGe, GaAs, AlGaAs, InP, GaInAsP, GaP, InGaAs, GaN, SiC, and the like. Also, an N-type impurity introduction layer 84 spaced apart from the N-type impurity introduction layer 82 is formed in the P-type semiconductor layer 81. Then, between the N-type impurity introduction layers 82 and 84, a gate electrode 86 is formed on the P-type semiconductor layer 81 through a gate insulation film 85. Also, a material of the gate insulation film 85 may be, for example, a silicon oxide film. A material of the gate electrode 86 may be, for example, a polysilicon film. Also, the N-type impurity introduction layer 84 and the gate electrode 86 may constitute a read transistor that reads a charge stored in the photoelectric conversion layer 100.

Also, on the P-type semiconductor layer 81, an interlayer insulation layer 87 is formed to cover the gate electrode 86. In addition, an insulation layer 89 is formed on the interlayer insulation layer 87, and a gate electrode 90 is buried in the insulation layer 89. Also, a buried electrode 88 is buried in the interlayer insulation layer 87, and the gate electrode 90 is connected to the N-type impurity introduction layer 84 through the buried electrode 88. Also, a material of the interlayer insulation layer 87 and the insulation layer 89 may be, for example, a silicon oxide film. A material of the gate electrode 90 may be, for example, a metal such as Cu. A material of the buried electrode 88 may be, for example, a metal such as W.

Also, a thin-film semiconductor layer 92 is formed on the gate electrode 90 through a gate insulation film 91. Also, a gate electrode 99 is formed on the thin-film semiconductor layer 92 through a gate insulation film 98. Also, an interlayer insulation layer 93 is formed on the gate insulation film 91, the thin-film semiconductor layer 92, and the gate electrode 99. A source layer 95 and a drain layer 97 are buried in the interlayer insulation layer 93. Then, the source layer 95 is connected to one end of the thin-film semiconductor layer 92 through a buried electrode 94, and the drain layer 97 is connected to the other end of the thin-film semiconductor layer 92 through a buried electrode 96. Also, a material of the thin-film semiconductor layer 92 may be, for example, an oxide semiconductor such as IGZO. A material of the gate insulation film 91 may be, for example, a silicon nitride film. A material of the gate insulation film 98 may be, for example, a silicon oxide film. A material of the gate electrode 90 may be, for example, a metal such as Cu. Materials of the source layer 95, the drain layer 97, and the gate electrode 99 may be, for example, metals such as Al, Cu, and Mo. Also, the gate electrodes 90 and 99, the thin-film semiconductor layer 92, the source layer 95, and the drain layer 97 may constitute a thin-film transistor that amplifies a signal read from the photoelectric conversion layer 100. The thin-film transistor may use any one of the structures of FIG. 1, FIG. 4, and FIGS. 6 to 11.

Then, when incident light RI is incident from a rear surface side of the P-type semiconductor layer 81, the incident light RI is converted into a charge by the photoelectric conversion layer 100 and the charge is stored in the photoelectric conversion layer 100. Then, the charge stored in the photoelectric conversion layer 100 is read through the read transistor, and is amplified by being applied to the gate electrode 90.

Here, since the thin-film transistor is formed on the photoelectric conversion layer 100, it becomes unnecessary to form an amplification transistor in the P-type semiconductor layer 81. Therefore, the area of the photoelectric conversion layer 100 of the P-type semiconductor layer 81 can be increased, and thus, the sensitivity of the solid-state imaging apparatus can be improved.

Also, by applying a positive voltage to the gate electrode 99, the capture and emission of carriers in a trap site at a channel interface can be reduced, and thus, 1/f noise of the thin-film transistor can be reduced. Also, the signal read through the read transistor may be applied to the gate electrode 99.

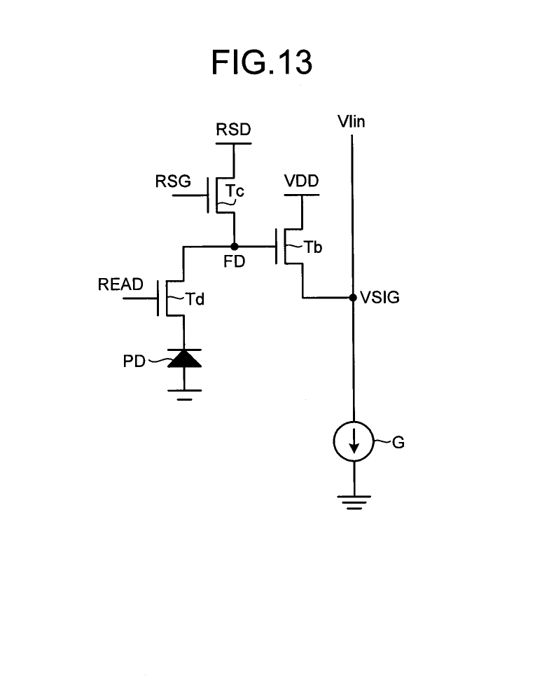

FIG. 13 is a diagram illustrating a circuit configuration of the pixel of FIG. 12.

Referring to FIG. 13, a photodiode PD, an amplification transistor Tb, a reset transistor Tc, and a read transistor Td are provided in the pixel. Also, as a detection node, a floating diffusion FD is formed at a connection point between the amplification transistor Tb, the reset transistor Tc, and the read transistor Td.

Then, a source of the read transistor Td is connected to the photodiode PD, and a read signal READ is inputted to a gate of the read transistor Td. Also, a source of the reset transistor Tc is connected to a drain of the read transistor Td, a reset signal RSG is inputted to a gate of the reset transistor Tc, and a drain of the reset transistor Tc is connected to a power potential RSD. Also, a source of the amplification transistor Tb is connected to a vertical signal line Vlin, a gate of the amplification transistor Tb is connected to the drain of the read transistor Td, and a drain of the amplification transistor Tb is connected to a power potential VDD. Then, a current source G is connected to the vertical signal line Vlin in each column.

Here, the photoelectric conversion layer 100 of FIG. 12 may constitute the photodiode PD. The N-type impurity introduction layer 84 and the gate electrode 86 of FIG. 12 may constitute the read transistor Td. Also, the gate electrodes 90 and 99, the thin-film semiconductor layer 92, the source layer 95, and the drain layer 97 of FIG. 12 may constitute the amplification transistor Tb. The thin-film transistor may constitute the reset transistor Tc.

### Thirteenth Embodiment

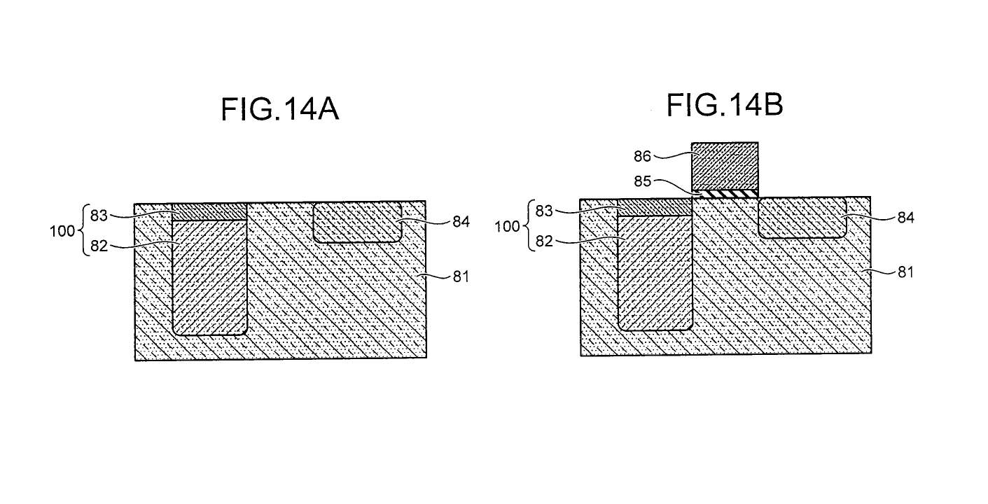

FIGS. 14A to 21A and 14B to 21B are cross-sectional views illustrating a method for manufacturing a pixel of a solid-state imaging apparatus according to a thirteenth embodiment.

Referring to FIG. 14A, an N-type impurity introduction layer 82 is formed by ion-implanting N-type impurities such as As or P into a P-type semiconductor layer 81. Subsequently, a P-type impurity introduction layer 83 is formed by ion-implanting P-type impurities such as B onto the N-type impurity introduction layer 82.

Subsequently, as illustrated in FIG. 14B, a gate insulation film 85 is formed on the P-type semiconductor layer 81 by a method such as thermal oxidation. Then, an electrode material is formed on the gate insulation film 85 by a method such as sputtering or CVD. Then, by patterning the electrode material by using a photolithography technique and an etching technique, a gate electrode 86 disposed next to the N-type impurity introduction layer 82 is formed on the gate insulation film 85. Subsequently, by ion-implanting N-type impurities such as As or P into the P-type semiconductor layer 81, an N-type impurity introduction layer 84 disposed next to the gate electrode 86 is formed to face the N-type impurity introduction layer 82.

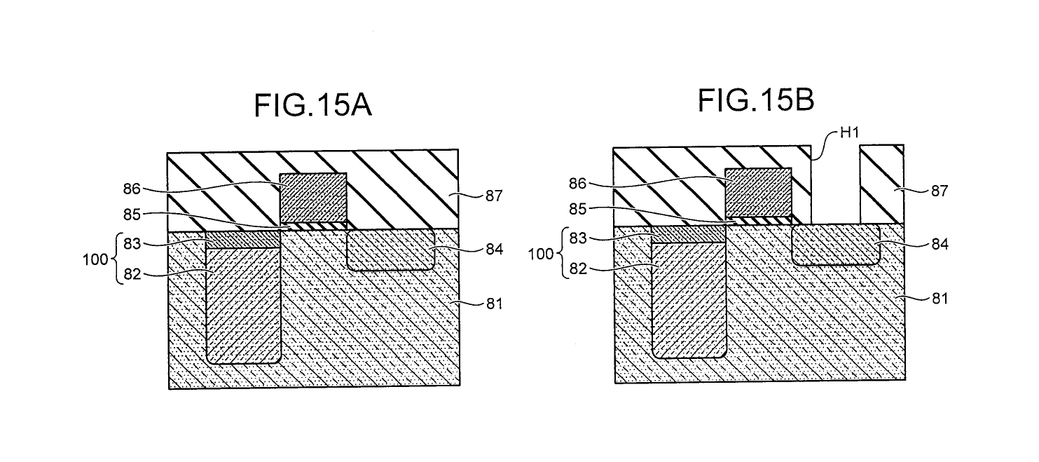

Subsequently, as illustrated in FIG. 15A, an interlayer insulation layer 87 is formed on the P-type semiconductor layer 81 by a method such as CVD, such that the gate electrode 86 is covered. Then, the interlayer insulation layer 87 is planarized by thinning the interlayer insulation layer 87 by a method such as CMP.

Subsequently, as illustrated in FIG. 15B, by patterning the interlayer insulation layer 87 by using a photolithography technique and a dry etching technique, an opening portion H1 exposing the N-type impurity introduction layer 84 is formed on the interlayer insulation layer 87.

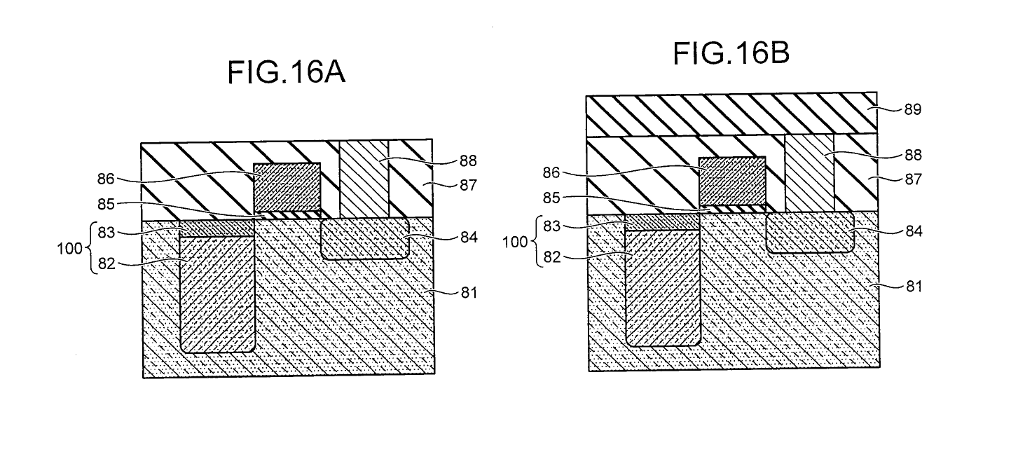

Subsequently, as illustrated in FIG. 16A, an electrode material is formed on the interlayer insulation layer 87 by a method such as sputtering or CVD, such that the opening portion H1 is buried. Then, by thinning the electrode material by a method such as CMP until the interlayer insulation layer 87 is exposed, a buried electrode 88 buried in the opening portion H1 is formed on the N-type impurity introduction layer 84.

Subsequently, as illustrated in FIG. 16B, an insulation layer 89 is formed on the interlayer insulation layer 87 and the buried electrode 88 by a method such as CVD.

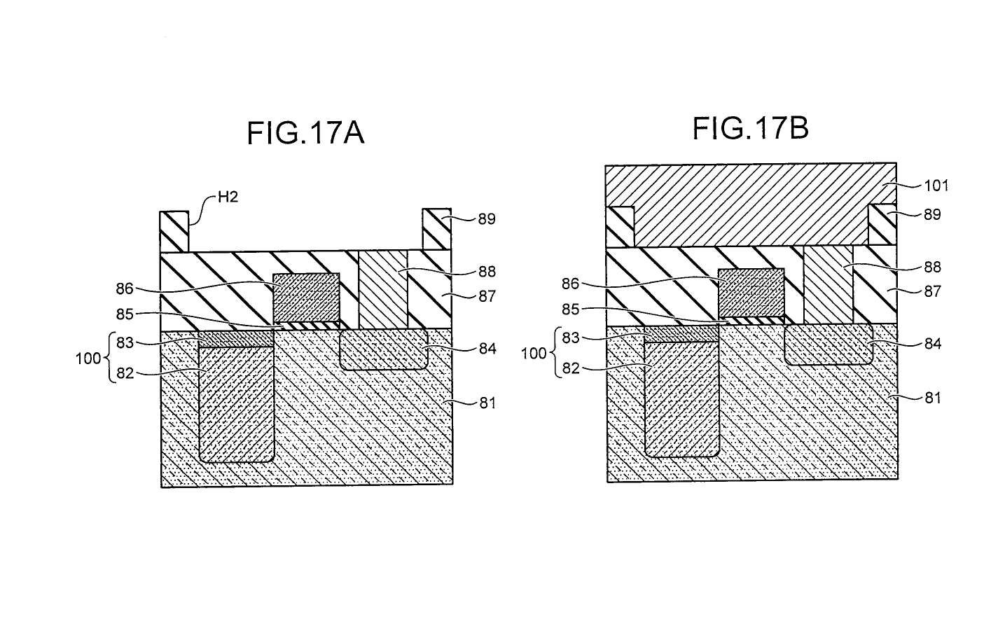

Subsequently, as illustrated in FIG. 17A, by patterning the insulation layer 89 by using a photolithography technique and a dry etching technique, an opening portion H2 exposing the buried electrode 88 is formed on the insulation layer 89.

Subsequently, as illustrated in FIG. 17B, an electrode material 101 is formed on the insulation layer 89 and the buried electrode 88 by a method such as sputtering or CVD, such that the opening portion H2 is buried. Also, a barrier metal film such as TaN may be formed under the electrode material 101.

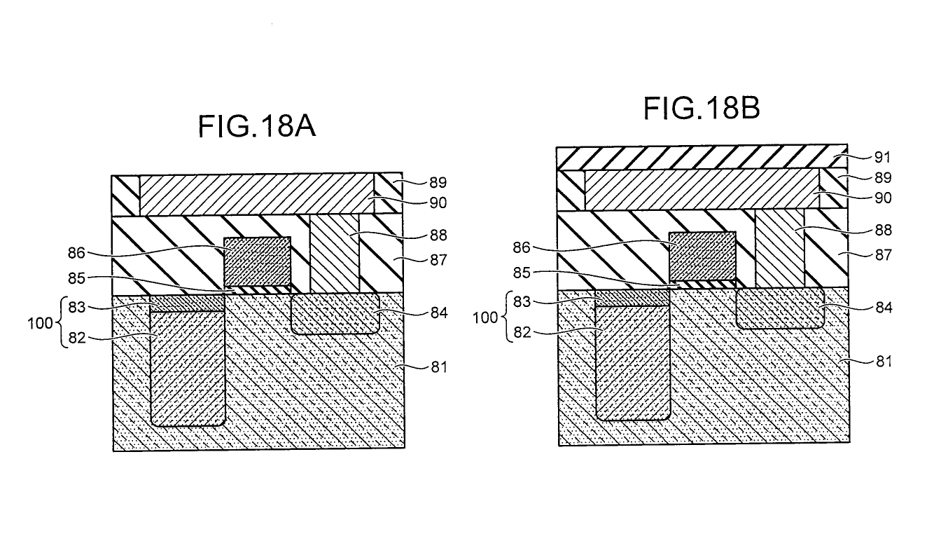

Subsequently, as illustrated in FIG. 18A, by thinning the electrode material 101 by a method such as CMP until exposing the insulation layer 89, a gate electrode 90 buried in the opening portion H2 is formed on the interlayer insulation layer 87.

Subsequently, as illustrated in FIG. 18B, a gate insulation film 91 is formed on the gate electrode 90 and the insulation layer 89 by a method such as CVD.

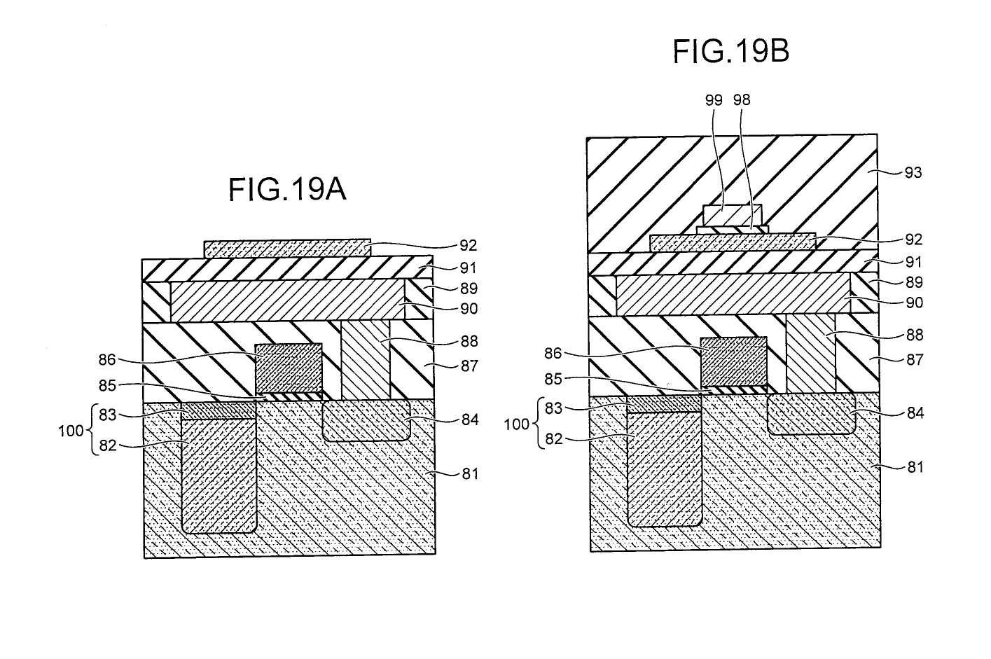

Subsequently, as illustrated in FIG. 19A, a thin-film semiconductor layer 92 is formed on the gate insulation film 91 by a method such as sputtering or CVD. Then, by using a photolithography technique and an etching technique, the thin-film semiconductor layer 92 is patterned to face the gate electrode 90.

Subsequently, as illustrated in FIG. 19B, a gate insulation film 98 is formed on the thin-film semiconductor layer 92 by a method such as CVD. Then, both end portions of the thin-film semiconductor layer 92 are exposed by patterning the gate insulation film 98 by using a photolithography technique and a dry etching technique. Then, an electrode material is formed on the gate insulation film 98 by a method such as sputtering or CVD. Then, by patterning the electrode material by using a photolithography technique and an etching technique, a gate electrode 99 disposed to face the gate electrode 90 without overlapping end portions of the thin-film semiconductor layer 92 is formed on the gate insulation film 98. In addition, the interlayer insulation layer 93 is formed on the gate insulation film 91 and the thin-film semiconductor layer 92 by a method such as CVD, such that the gate electrode 99 is covered.

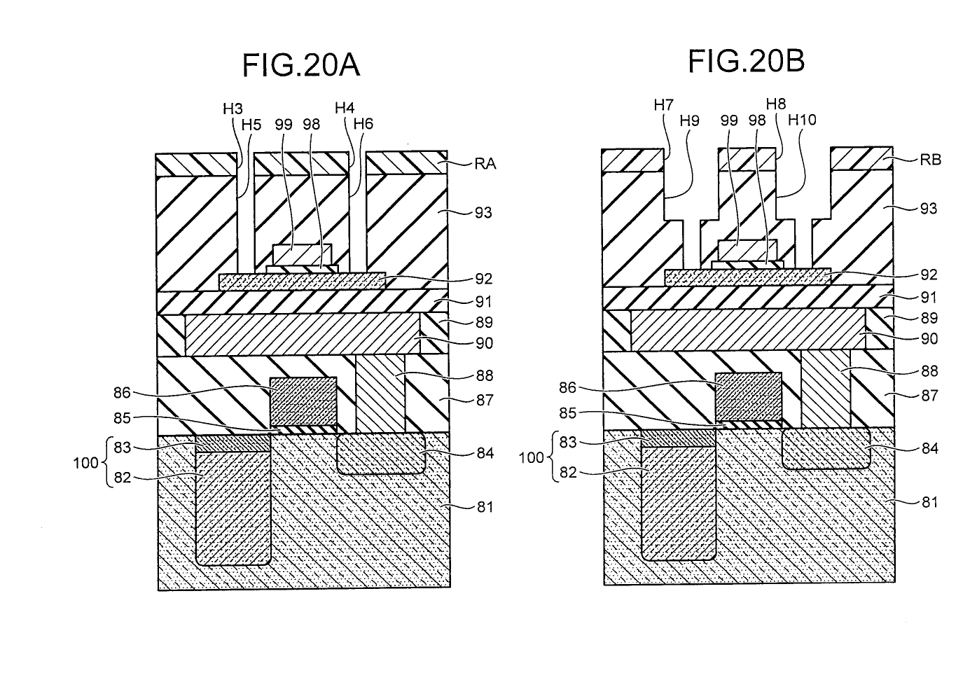

Subsequently, as illustrated in FIG. 20A, by using a photolithography technique, a resist pattern RA provided with opening portions H3 and H4 are formed on the interlayer insulation layer 93. Then, by etching the interlayer insulation layer 93 using the resist pattern RA as a mask, opening portions H5 and H6 exposing the end portions of the thin-film semiconductor layer 92 are formed in the interlayer insulation layer 93.

Subsequently, as illustrated in FIG. 20B, by using a photolithography technique, a resist pattern RB provided with opening portions H7 and H8 are formed on the interlayer insulation layer 93. Then, by etching the interlayer insulation layer 93 using the resist pattern RB as a mask, grooves H9 and H10 connected to the opening portions H5 and H6 are formed in the interlayer insulation layer 93.

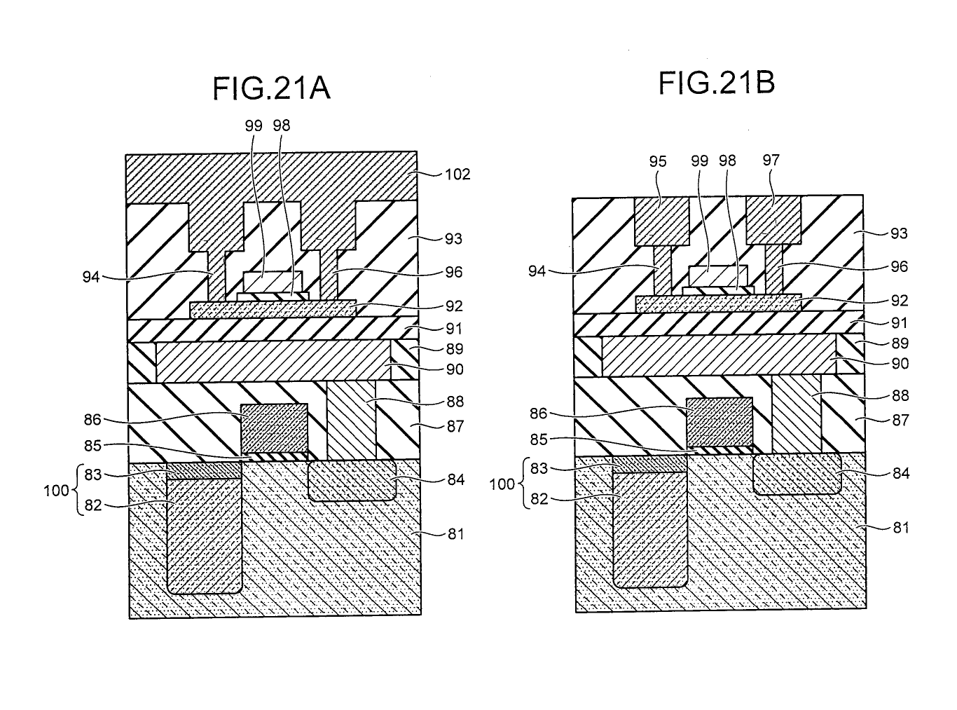

Subsequently, as illustrated in FIG. 21A, an electrode material 102 is formed on the interlayer insulation layer 93 by a method such as sputtering or CVD, such that the opening portions H5 and H6 and the grooves H9 and H10 are buried.

Subsequently, as illustrated in FIG. 21B, by thinning the electrode material 102 by a method such as CMP until the interlayer insulation layer 93 is exposed, buried electrodes 94 and 96 buried respectively in the opening portions H5 and H6 are formed on the thin-film semiconductor layer 92, and a source layer 95 and a drain layer 97 connected respectively to the buried electrodes 94 and 96 are buried in the grooves H9 and H10.

Also, in the above-described embodiment, it has been described that the first gate electrode such as the gate electrode 3, 23, 53, 63 or 90 is disposed under the source layer and the drain layer. However, the first gate electrode may be disposed under the source layer and the drain layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A thin-film transistor comprising:
a thin-film semiconductor layer;
a first gate electrode provided on the thin-film semiconductor layer through a first gate insulation film without overlapping an edge portion of the thin-film semiconductor layer;
a source layer connected to the thin-film semiconductor layer; and
a drain layer connected to the thin-film semiconductor layer.

2. The thin-film transistor according to claim 1, comprising a second gate electrode provided through a second gate insulation film on an opposite surface of the thin-film semiconductor layer on which the first gate electrode is disposed without overlapping the edge portion of the thin-film semiconductor layer.

3. The thin-film transistor according to claim 2, comprising an interconnection connecting the first gate electrode and the second gate electrode.

4. The thin-film transistor according to claim 1, comprising an edge control layer disposed on the edge portion of the thin-film semiconductor layer between the drain layer and the source layer to control a potential of the edge portion of the thin-film semiconductor layer.

5. The thin-film transistor according to claim 4, wherein the edge control layer is a charged film.

6. The thin-film transistor according to claim 1, wherein the drain layer has a larger overlapping area with respect to the first gate electrode than the source layer.

7. The thin-film transistor according to claim 1, wherein the drain layer is disposed without overlapping the edge portion of the thin-film semiconductor layer in a gate width direction.

8. The thin-film transistor according to claim 1, wherein the thin-film semiconductor layer is more widened in a gate width direction at a side of the drain layer than at a side of the source layer.

9. The thin-film transistor according to claim 1, wherein the thin-film semiconductor layer is more widened in a gate width direction than the drain layer and the source layer.

10. A thin-film transistor comprising:
a thin-film semiconductor layer;
a gate electrode provided on the thin-film semiconductor layer through a gate insulation film;
a source layer connected to the thin-film semiconductor layer; and
a drain layer connected to the thin-film semiconductor layer and having a larger overlapping area with respect to the gate electrode than the source layer.

11. The thin-film transistor according to claim 10, wherein the drain layer is disposed without overlapping the edge portion of the thin-film semiconductor layer in a gate width direction.

12. The thin-film transistor according to claim 10, wherein the thin-film semiconductor layer is more widened in a gate width direction at a side of the drain layer than at a side of the source layer.

13. The thin-film transistor according to claim 10, wherein the thin-film semiconductor layer is more widened in a gate width direction than the drain layer and the source layer.

14. The thin-film transistor according to claim 10, wherein the thin-film semiconductor layer has an edge portion curved between the drain layer and the source layer.

15. A solid-state imaging apparatus comprising:
a semiconductor layer in which a photoelectric conversion layer is formed;
a read transistor formed on the semiconductor layer to read a charge stored in the photoelectric conversion layer; and
a thin-film transistor formed over the read transistor to amplify a signal read through the read transistor,
wherein the thin-film transistor comprises:
a thin-film semiconductor layer;
a first gate electrode provided on the thin-film semiconductor layer through a first gate insulation film without overlapping an edge portion of the thin-film semiconductor layer;
a source layer connected to the thin-film semiconductor layer; and
a drain layer connected to the thin-film semiconductor layer.

16. The solid-state imaging apparatus according to claim 15, comprising a second gate electrode provided through a second gate insulation film on an opposite surface of the thin-film semiconductor layer on which the first gate electrode is disposed without overlapping the edge portion of the thin-film semiconductor layer.

17. The solid-state imaging apparatus according to claim 16, comprising an interconnection connecting the first gate electrode and the second gate electrode.

18. The solid-state imaging apparatus according to claim 16, comprising an edge control layer disposed on the edge portion of the thin-film semiconductor layer between the drain layer and the source layer to control a potential of the edge portion of the thin-film semiconductor layer.

19. The solid-state imaging apparatus according to claim 18, wherein the edge control layer is a charged film.

20. The solid-state imaging apparatus according to claim 15, wherein the drain layer has a larger overlapping area with respect to the first gate electrode than the source layer.
